(19) United States
(12) Patent Application Publication
(10) Pub. No.: US 2005/0265000 A1
(43) Pub. Date: Dec. 1, 2005

(54) Heat sink assembly with fixing devices

(75) Inventor: Li He, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: Foxconn Technology Co., Ltd., Tu-Cheng City (TW)

(21) Appl. No.: 11/114,700

(22) Filed: Apr. 25, 2005

(30) Foreign Application Priority Data
May 26, 2004 (CN) 200420046452.5

(51) Int. Cl. H05K 7/20

(52) U.S. Cl. 361/709

(57) ABSTRACT

A heat sin assembly includes a heat sink and a fixing device. The heat sink assembly includes a heat-absorbing base, a heat pipe attached to base, and a plurality of stacked fins through which the heat pipe extends. A fixing device is detachably engaged with the base and defining a plurality of apertures therein far from the base. A plurality of fasteners is positioned into the apertures of the fixing device to be ready to secure the heat sink assembly. The fasteners are movable relative the fixing device when pressed. The fixing device is readily coupled to the heat sink and removed therefrom so that the heat sink assembly is easily updated with another fixing device.

### CROSS-REFERENCE TO RELATED APPLICATION

This application is related to one corresponding U.S. patent applications entitled “HEAT DISSIPATION DEVICE ASSEMBLY”, recently filed on Sep. 30, 2004 with application Ser. No. 10/955,610. The disclosure of the above-identified application is incorporated herein by reference.

### BACKGROUND OF THE INVENTION

1. Field of the Invention

The present invention generally relates to cooling of electronic devices, and particularly to heat sink assembly with a fixing device which can be readily coupled to the heat sink and removed therefrom.

2. Prior Art

Developments in integrated circuits technology have led to remarkable improvements of performances of electronic devices. During operation of many contemporary electronic devices, large amounts of heat are produced. Such heat must be efficiently dissipated out from the electronic devices, to prevent it from becoming unstable or being damaged. Typically, a heat sink is attached to an outer surface of the electronic devices to facilitate dissipation of heat therefrom.

A conventional heat sink assembly often uses a clip to attach a heat sink to an electronic device. The clip is placed into a channel of the heat sink and presses a top surface of a base of the heat sink. However, the channel is a space which would otherwise be occupied by a number of heat-dissipating fins. This results in lower heat dissipation efficiency of the heat sink.

A heat sink assembly using a clip placed under the heat sink to attach the heat sink to the electronic device is developed. An example of such an assembly is disclosed in U.S. Pat. No. 6,851,467 B1. It is apparently seen the heat sink has a bulky heat dissipating portion and a contrastively small base for fitting in with great heat generated by a central process unit (CPU) and high density of other electronic elements around the CPU on a printed circuit board. In order to fasten the heat sink to the CPU firmly, a clip is positioned in a groove around a conductive core of the heat sink and cannot be removed unless other components of the heat sink assembly are not disassembled. As a result, the heat sink assembly cannot be used to other situation where the printed circuit board is provided a different engaging structure except that the whole heat sink assembly is disassembled and updated with another suitable clip coupled to the heat sink. Operation of updating the heat sink assembly with another clip is cumbersome. This leads to that the heat sink is used narrowly.

Therefore, an improved heat sink assembly which overcomes above problems is desired.

### SUMMARY OF THE INVENTION

Accordingly, what is needed is to provide a heat sink assembly with a fixing device which is readily assembled to and removed from a heat sink for substitution.

A heat sink assembly of an embodiment of the invention comprises a heat-absorbing base, a heat pipe attached to base, and a plurality of stacked fins through which the heat pipe extends. A fixing device is detachably engaged with the base and defining a plurality of apertures therein far from the base. A plurality of fasteners is positioned into the apertures of the fixing device to be ready to secure the heat sink assembly.

Another embodiment of the invention comprises a heat sink and a fixing device. The heat sink includes a base, with a step formed on a periphery face of the base, a plurality of fins above the base, and at least a heat pipe which is attached to the base and extends away from the base and through the fins. An accommodating space is defined between the step and the fins, around the base. The fixing device comprises a frame defining an opening for receiving the base. The frame is removably positioned in the accommodating space, surrounding the base, and abutting against the step thereof for preventing the fixing device from separation from the heat sink. A plurality of fixing arms extends from the frame for receiving fasteners.

Other, advantages and novel features of the present invention will be drawn from the following detailed description of some embodiments of the present invention together with the attached drawings, in which:

### BRIEF DESCRIPTION OF THE DRAWINGS

FIG. 1 is an exploded view of a heat sink assembly with fixing devices of a preferred embodiment in accordance with the present invention;

FIG. 2 is a partly assembled view of FIG. 1;

FIG. 3 is a fully assembled view of FIG. 1;

FIG. 4 is an exploded isometric view showing a base and a fixing device of a second embodiment;

FIG. 5 is an exploded isometric view showing a base and a fixing device of a third embodiment;

FIG. 6 is an assembled view of FIG. 5; and

FIG. 7 is an exploded view showing a base and a fixing device of a fourth embodiment.

### DETAILED DESCRIPTION OF THE INVENTION

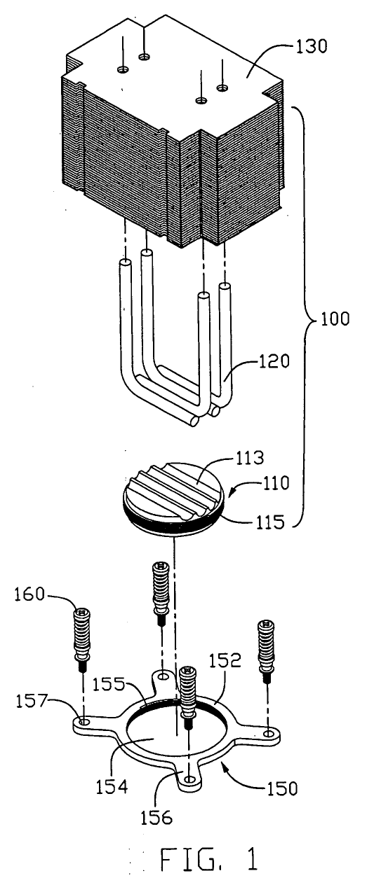

In the following detailed description of the embodiment, reference is made to the accompanying drawings that illustrate embodiments of the present invention and their practices. FIG. 1 shows a heat dissipation assembly like a heat sink assembly of a preferred embodiment in accordance with the present invention. The heat sink assembly is for being mounted to a printed circuit board (not shown) to contact an electronic device or a heat source, such as a CPU (not shown), for heat dissipation. The heat sink assembly comprises a heat sink 100, a fixing device 150 and a plurality of fasteners 160.

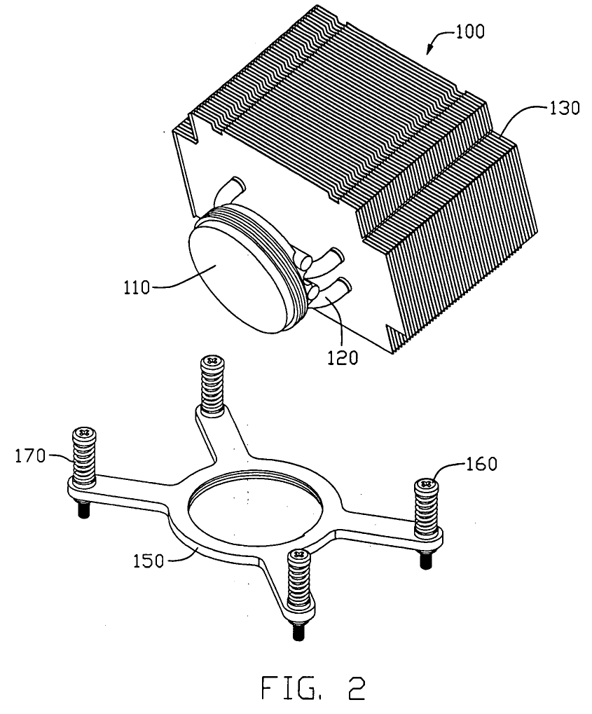

Please refer to FIG. 2 together with FIG. 1, the heat sink 100 has a disc-shaped base 110. The base 110 has a bottom face (not labeled) for contacting the CPU, a top face (not labeled) opposing the bottom face and defining two pair of parallel grooves 113, and a periphery face (not labeled) between the bottom face and the top face. The periphery face defines continuous external screw thread 115. Two pairs of L-shaped heat pipes 120 are attached to the base 110, with one end of each heat pipe 120 is fixedly received in a corresponding groove 113 of the base 110. Another end of each heat pipe 120 extends away from the top face of the base 110 and through a plurality of stacked fins 130 which are parallel to the top face of the base 110.

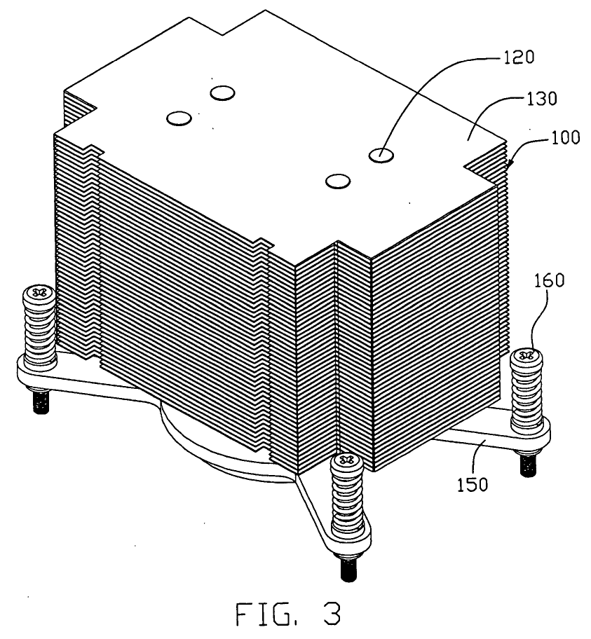

The fixing device 150 includes a frame 152 defining a circular opening 154 with continuous inner screw thread 155 for engaging with the external screw thread 115 on the base 110 of the heat sink 100. Two pairs of clamping arms 156 extend from the frame 152 outwardly. An aperture 157 for receiving a fastener 160, such as bolt, is defined on each clamping arm 156 near to free end thereof. The fixing device 150 can be coupled to the heat sink 100 by rotating the fixing device 150 relative to the heat sink 100 to reach a full engagement between the internal screw thread 155 of the fixing device 150 and the external screw thread 115 of the base 110. Each fastener 160 extends through a spring 170 and is received in one aperture 157 of the fixing device 150. The springs 170 on the fasteners 160 are compressed lightly to make the fasteners 160 positioned in the apertures 157 of the clamping arms 156 and movable up and down relative to the clamping arms 156 when the fasteners 160 are pressed. The fasteners 160 may be driven to extend tightly into holes of the printed circuit board to clamp the heat sink assembly down against the CPU. Combination of the heat sink 100 and the fixing device 150 is shown in FIG. 3. The fixing device 150 can be removed conveniently from the heat sink 100 by reversely rotating the fixing device 150 relative to the heat sink 100.

From above description of the preferred embodiment, we see that the fixing device 150 can be coupled to the heat sink 100 readily and removed therefrom by rotation of the fixing device 150 relative to the heat sink 100, without disassembling the heat sink 100. Thus, the heat sink assembly can be readily updated by displacing the fixing device 150 with another one that has a different dimension, such as longer clamping arms. The updated heat sink assembly can be used to another situation where there is a different engaging structure corresponding to the updated heat sink assembly.

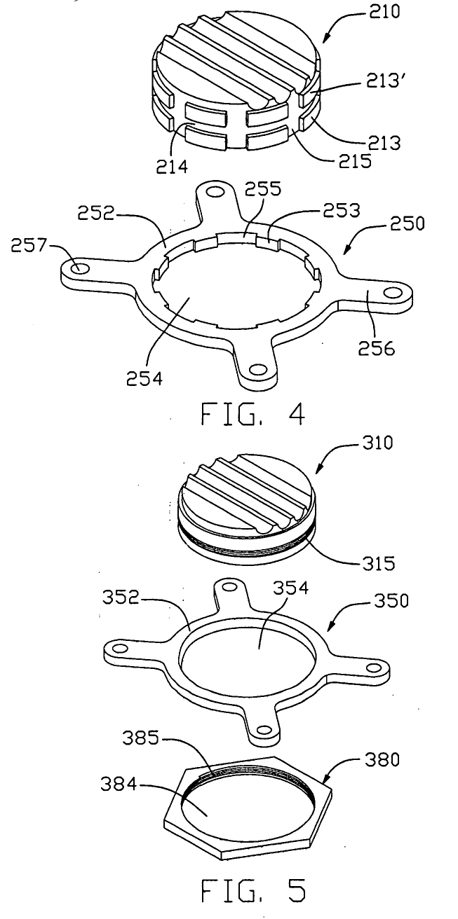

Engagement between the base of the heat sink and the fixing device in the present invention is not limited to the preferred embodiment as above-mentioned. It can be achieved by other variations. FIG. 4 illustrates a second embodiment of the present invention. It has the same heat pipes, fins and fasteners as the first embodiment. For concision, only a disc-shaped base 210 of a heat sink (not shown) and a fixing device 250 are shown in FIG. 4. In this embodiment, a plurality of first external teeth 213 and second external teeth 213′ extend radially outwardly from a periphery face of the base 210. The first external teeth 213 are spaced evenly apart by a series of external gaps 215, so the second external 213′ teeth are. The first external teeth 213 and second external teeth 213′ are opposed to and separated from each other by a groove 214 therebetween. The fixing device 250 has a frame 252 defining an opening 254 in a center thereof. A plurality of internal teeth 253 extend radially inwardly from an inner periphery of the frame 252, corresponding to the external gaps 215 of the base 210. Adjacent internal teeth 253 are separated by an internal gap 255. Similar to the first embodiment, the fixing device 250 has two pairs of clamping arms 256 extending from the frame 252 and defining apertures 257 thereon. When assembly, the base 210 is disposed above the fixing device 250, the first external teeth 213 of the base 210 oppose the internal gaps 255 of the fixing device 250. The first external teeth 213 pass through the internal gaps 255, and the frame 252 of the fixing device 250 is positioned between the first external teeth 213 and the second external teeth 213′ and within the groove 214 of the base 210. Then, the fixing device 250 is rotated until the internal teeth 253 of the fixing device 250 abut the corresponding first external teeth 213 of the base 210. The fixing device 250 is thereby prevented from separation from the base 210 of the heat sink. The fixing device 250 can be removed readily from the heat sink by rotation of the fixing device 250 until the first external teeth 213 oppose the internal gap 255.

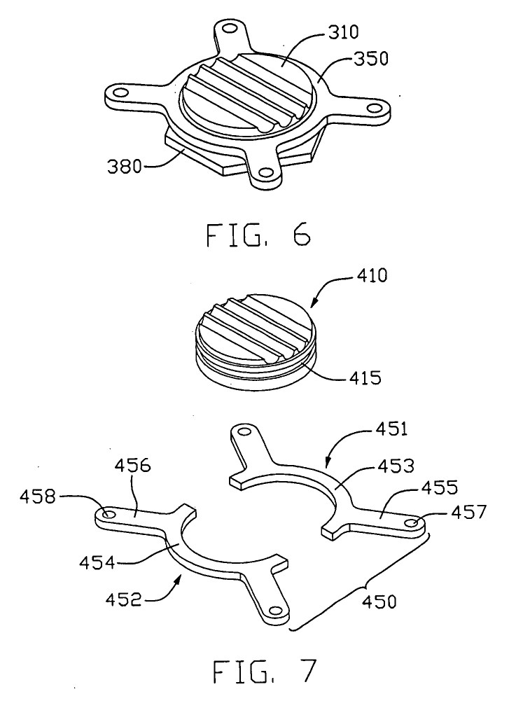

FIG. 5 and FIG. 6 show a third embodiment of the present invention. Also for concision, only a base 310 of a heat sink, a fixing device 350 and a stopping ring 380 are shown. The base 310 comprises an upper section (not labeled) and a lower section 315 which is threaded around thereof. The stopping ring 380 defines an opening 384 with an internal screw thread 385 for engaging with the lower section 315 of said base 310. The fixing device 350 has a frame 352 defining an opening 354 corresponding to the base 310, and clamping arms (not labeled) same as that in the first embodiment. Referring to FIG. 6, when assembly, the lower section 315 of the base 310 passes through the opening 354 of the fixing device 350 and screws into the opening 384 of the stopping ring 380. The frame 352 of the fixing device 350 is positioned in an accommodating space between the stopping ring 380 and the fins (not shown) and surrounds the upper section of the base 310, being prevented from escaping from the base 310. The fixing device 350 can be removed readily from the heat sink after the stopping ring 380 is screwed off.

For further sufficiently understand the present invention, a fourth embodiment is disclosed as follows. Referring to FIG. 7, only a base 410 and a fixing device 450 is shown also for concision. Other elements, such as heat pipes, fins are same as that in the first embodiment and not shown in FIG. 7. The base 410 defines an annular groove 415 around thereof. The fixing device 450 is divided into two pieces and has a pair of sub-frames 451, 452. Each sub-frame 451, 452 has a semicircle hooping portion 453, 454 which has the same thickness as the width of the groove 415 of the base 410. Each sub-frame 451, 452 has two clamping arms 455, 456 which extend from the hooping portion 453, 454 and define apertures 457, 458. When assembly, the two sub-frames 451, 452 are respectively received in the annular groove 415 of the base 410 and jointed into a frame around the base 11d, forming a Provisional combination of the heat sink (not shown) and the fixing device 450. When several fasteners (not shown) extend the apertures 457, 458 of the fixing device 450 and into holes (not shown) in a printed circuit board (not shown), the pair of sub-frames 451, 452 are fixedly coupled to the heat sink and the assembly is mounted on the printed circuit. The fixing device 450 can be removed readily from the heat sink after the fasteners is pulled out of the holes of the printed circuit board.

It is recognized that the invention may be susceptible to various other modifications and alternative constructions in view of this disclosure. Although the invention has been shown and described in detail herein by a preferred embodiment and certain alternatives, it should be understood that there is no intention of limiting the invention strictly to this. But rather it is the intention to cover all such other modifications and alternative constructions falling within the spirit and scope of the invention as defined in the appended claims.

1. A heat sink assembly comprising:
a heat sink including a base with a step formed on a periphery face thereof, and a plurality of fins above the base, at least a heat pipe which is attached to the base and extends away from the base and through the fins; an accommodating space being defined between the step and the fins, around the base; and
a fixing device comprising a frame defining an opening for receiving the base, the frame removably positioned in the accommodating space, surrounding the base, and abutting against the step thereof, a plurality of fixing arms extending from the frame for receiving fasteners.

2. The heat sink assembly in claim 1, wherein a plurality of first external teeth extends outwardly from the periphery face of the base and is separated by a plurality of internal gaps, and wherein a plurality of internal teeth extends inwardly from an inner edge of the opening of the fixing device and alternatively arranged with the first external teeth.

3. The heat sink assembly in claim 2, wherein the internal teeth of the fixing device abut against the first external teeth of the base after the frame of the fixing device is disposed in the accommodating space.

4. The heat sink assembly in claim 3, wherein a plurality of second external teeth extends outwardly from the periphery of the base and is separated from the first external teeth by a groove, the frame of the fixing device is positioned in the groove and sandwiched between the first external teeth and the second external teeth.

5. The heat sink assembly in claim 3, wherein each clamping arm defines an aperture, the apertures receiving the fasteners.

6. The heat sink assembly in claim 5, wherein each fastener extends through a spring, then through the aperture.

7. The heat sink assembly in claim 1, wherein a stopping ring is screwed to the base to support the fixing device.

8. The heat sink assembly in claim 1, wherein an annular groove is defined on the periphery face of the base and adjacent to the step.

9. The heat sink assembly in claim 8, wherein the frame of the fixing device comprises a pair of sub-frames coupled to a frame received in the groove and surrounding the base.

10. A heat sink assembly comprising:
a heat-absorbing base;
a plurality of stacked fins parallel to the base;
a heat pipe rendering the fins to be thermally connected to the base;
a fixing device detachably engaged with the base and defining a plurality of apertures therein far from the base; and
a plurality of fasteners positioned into the apertures to be ready to secure the heat sink assembly, and movable relative to the fixing device when pressed.

11. The heat sink assembly of claim 10, wherein each fastener pulls on a spiral spring compressed between one end of the fastener and the fixing device.

12. The heat sink assembly of claim 10, wherein the fixing device is flat-plate-typed.

13. The heat sink assembly of claim 10, wherein the base is disc-shaped.

14. The heat sink assembly of claim 10, wherein the fixing device is screwedly engaged with the base.

15. The heat sink assembly of claim 13, wherein a plurality of first external teeth extends outwardly from a periphery face of the base and is separated by a plurality of internal gaps, and wherein the fixing device comprises a frame defining an opening, a plurality of internal teeth extends inwardly from an inner edge of the opening of the fixing device and alternatively arranged with the first external teeth.

16. The heat sink assembly in claim 15, wherein the internal teeth of the fixing device abut against the first external teeth of the base for prevent the fixing device from escaping from the base of the heat sink.

17. The heat sink assembly in claim 16, wherein a plurality of second external teeth extends outwardly from the periphery of the base and is separated from the first external teeth by a groove, the frame of the fixing device is positioned in the groove and sandwiched between the first external teeth and the second external teeth.

18. The heat sink assembly in claim 13, wherein a stopping ring is screwed to the base to stop the fixing device escaping from the base.

19. The heat sink assembly in claim 13, wherein the base defines an annular groove around thereof and the frame of the fixing device comprises a pair of divided sub-frames received in the groove.

20. A heat dissipation assembly comprising:
a base for absorbing heat by means of a thermal contact thereof with a heat source;
a plurality of fins arranged beside said base for dissipating said heat;
a heat pipe disposed between said base and said plurality of fins and thermally contactable with said base and said plurality of fins respectively so as to transmit said heat from said base to said plurality of fins, portions of said heat pipe protrudently extendable into said base for being thermally contactable with said base; and
a fixing device detachably engaged with the base and having a plurality of fasteners fixable around said base for urging said base to move toward said heat source for said thermal contact of said base with said heat source by means of engagement between said fixing device and said base.
